(19) United States
(12) Patent Application Publication
(10) Pub. No.: US 2015/0013590 A1
(43) Pub. Date: Jan. 15, 2015

(54) SEED CRYSTAL HOLDING SHAFT FOR USE IN SINGLE CRYSTAL PRODUCTION DEVICE, AND METHOD FOR PRODUCING SINGLE CRYSTAL

(71) Applicants: TOYOTA JIDOSHA KABUSHIKI KAISHA, Toyota-shi (JP); NIPPON STEEL & SUMITOMO METAL CORPORATION, Chiyoda-ku (JP)

(72) Inventors: Motohisa Kado, Toyota-shi (JP); Kazuhiko Kusunoki, Chiyoda-ku (JP)

(73) Assignees: TOYOTA JIDOSHA KABUSHIKI KAISHA, Toyota-shi (JP); NIPPON STEEL & SUMITOMO METAL CORPORATION, Chiyoda-ku (JP)

(21) Appl. No.: 14/373,194

(22) PCT Filed: Dec. 27, 2012
(86) PCT No.: PCT/JP2012/083993

§ 371 Date: Jul. 18, 2014

(30) Foreign Application Priority Data
Jan. 20, 2012 (JP) 2012-010469

(51) Int. Cl. C30B 19/06; C30B 29/36; C30B 19/04

(52) U.S. Cl. CPC C30B 19/062; C30B 19/04; C30B 19/068; C30B 29/36
USPC 117/60; 117/206

(57) ABSTRACT

The aim of the present invention is to provide a seed crystal holding shaft that is used in a device for producing single crystals by a solution process that allows for faster growth of SiC single crystals than in the past, and a method for producing single crystals by the solution process. The seed crystal holding shaft used in a device for producing single crystals by the solution process is a seed crystal holding shaft wherein at least a portion of a side of the seed crystal holding shaft is covered by a reflectance member having a higher reflectance than the reflectance of the seed crystal holding shaft and the reflector member is disposed such that there is a space between the reflector member and the seed crystals held on the end face of the seed crystal holding shaft.

### TECHNICAL FIELD

The present invention relates to a seed crystal holding shaft to be used in a single crystal production device based on a solution process, and to a method for producing a single crystal.

### BACKGROUND ART

SiC single crystals are thermally and chemically very stable, superior in mechanical strengths, and resistant to radiation, and also has superior physical properties, such as high dielectric breakdown voltage and high thermal conductivity compared to Si single crystals. They are therefore able to exhibit high output, high frequency, voltage resistance and environmental resistance that cannot be realized with existing semiconductor materials, such as Si single crystals and GaAs single crystals, and are considered ever more promising as next-generation semiconductor materials for a wide range of applications including power device materials that allow high power control and energy saving to be achieved, device materials for high-speed large volume information communication, high-temperature device materials for vehicles, radiation-resistant device materials and the like.

Typical growth processes for growing SiC single crystals that are known in the prior art include gas phase processes, the Acheson process and solution processes. Among gas phase processes, for example, sublimation processes have a drawback in that grown single crystals have been prone to hollow penetrating defects known as “micropipe defects”, lattice defects, such as stacking faults, and generation of polymorphic crystals. However, most SiC bulk single crystals are conventionally produced by sublimation processes because of the high crystal growth rate, with attempts being made to reduce defects in the grown crystals (PTL 1). In the Acheson process, heating is carried out in an electric furnace using silica stone and coke as starting materials, and therefore it has not been possible to obtain single crystals with high crystallinity due to impurities in the starting materials.

Solution processes are processes in which molten Si or an alloy melted in molten Si is situated in a graphite crucible and C is dissolved from the graphite crucible into the molten liquid, and a SiC crystal layer is deposited and grown on a seed crystal substrate set in the low temperature section. Solution processes are most promising for reducing defects since crystal growth is carried out in a state of near thermal equilibrium, compared to gas phase processes. Recently, therefore, methods for producing SiC single crystals by solution processes have been proposed (PTL 2).

### CITATION LIST

### Patent Literature

[PTL 1] Japanese Unexamined Patent Publication No. 2003-119097

[PTL 2] Japanese Unexamined Patent Publication No. 2008-105896

### SUMMARY OF THE INVENTION

### Problems to be Solved by the Invention

In a solution process, the degree of supersaturation is the driving force of crystal growth. Consequently, increasing the degree of supersaturation can increase the crystal growth rate. For growth of a SiC single crystal by a solution process, the degree of supersaturation is provided by lowering the temperature of the Si—C solution near the crystal growth interface so that it is a lower temperature than the internal temperature of the Si—C solution. In order to increase the SiC single crystal growth rate, therefore, it is necessary for the temperature of the Si—C solution near the crystal growth interface to be a lower temperature, to ensure a higher degree of supersaturation. However, it has been difficult to lower the temperature near the crystal growth interface while maintaining a high internal temperature of the Si—C solution, so as to increase the temperature difference to a degree allowing the desired SiC single crystal growth rate to be obtained.

It is an object of the present invention to solve these problems by providing a seed crystal holding shaft to be used in a single crystal production device employed in a solution process that allows more rapid SiC single crystal growth than the prior art, and a process for producing a single crystal based on a solution process.

### Means for Solving the Problems

The invention provides a seed crystal holding shaft to be used in a single crystal production device employed in a solution process, wherein

at least a portion of the side face of the seed crystal holding shaft is covered with a reflector member having higher reflectance than the reflectance of the seed crystal holding shaft, and

the reflector member is disposed so as to leave a gap between the reflector member and the seed crystal held on the end face of the seed crystal holding shaft.

The invention also provides a process for producing a SiC single crystal by a solution process in which a SiC seed crystal held on a seed crystal holding shaft is contacted with a Si—C solution that has been heated so as to have a temperature gradient with increasing temperature from the inside to the surface of the Si—C solution in a crucible by a heating apparatus situated around the crucible, to grow a SiC single crystal from the seed crystal, wherein

at least a portion of the side face of the seed crystal holding shaft is covered with a reflector member having higher reflectance than the reflectance of the seed crystal holding shaft, and

the reflector member is disposed so as to leave a gap between the reflector member and the seed crystal.

### Effect of the Invention

According to the invention it is possible to increase the rate of single crystal growth.

### BRIEF DESCRIPTION OF THE DRAWINGS

FIG. 1 is a cross-sectional schematic drawing showing an example of the construction of a SiC single crystal production device for carrying out the invention.

FIG. 2 is a cross-sectional schematic drawing showing an example of the basic construction of a SiC single crystal production device used in the prior art.

FIG. 3 is a cross-sectional schematic drawing showing an example of the basic construction of a SiC single crystal production device provided with a seed crystal holding shaft having a reflector member disposed on the side face, according to one embodiment of the invention.

FIG. 4 is a cross-sectional schematic drawing showing an example of the basic construction of a SiC single crystal production device provided with a seed crystal holding shaft having a reflector member disposed on the lower end of the side face, according to one embodiment of the invention.

FIG. 5 is a cross-sectional schematic drawing showing an example of the basic construction of a SiC single crystal production device provided with a seed crystal holding shaft having a reflector member disposed on the upper end of the side face, according to one embodiment of the invention.

FIG. 6 is a cross-sectional schematic drawing showing an example of the basic construction of a SiC single crystal production device provided with a seed crystal holding shaft having a reflector member disposed on several locations of the side face, according to one embodiment of the invention.

FIG. 7 is a cross-sectional schematic drawing showing the positional relationship between a seed crystal and a reflector member when holding the seed crystal having a top face with the same shape as the end face of the seed crystal holding shaft, according to one embodiment of the invention.

FIG. 8 is a cross-sectional schematic drawing showing the positional relationship between a seed crystal and a reflector member when holding the seed crystal having a top face with a smaller shape than the end face of the seed crystal holding shaft, according to one embodiment of the invention.

FIG. 9 is a cross-sectional schematic drawing showing the positional relationship between a seed crystal and a reflector member when holding the seed crystal having a top face with a larger shape than the end face of the seed crystal holding shaft, according to one embodiment of the invention.

FIG. 10 is a cross-sectional schematic drawing showing an example of the basic construction of a SiC single crystal production device provided with a seed crystal holding shaft having disposed on the side face a reflector member having a shape in which the lower end is thicker and the upper end is thinner, according to one embodiment of the invention.

FIG. 11 is a cross-sectional schematic drawing showing an example of the basic construction of a SiC single crystal production device provided with a seed crystal holding shaft having a thick reflector member disposed on the side face, according to one embodiment of the invention.

FIG. 12 is a photograph of the outer appearance of the SiC grown crystal obtained in Example 1, as observed from the side face.

FIG. 13 is a photograph of the outer appearance of the SiC grown crystal obtained in Comparative Example 1, as observed from the side face.

FIG. 14 is a photograph of the outer appearance of the SiC grown crystal obtained in Comparative Example 2, as observed from the side face.

FIG. 15 is a photograph of the outer appearance of the SiC grown crystal obtained in Comparative Example 3, as observed from the bottom face.

FIG. 16 is a photograph of the outer appearance of the SiC grown crystal obtained in Comparative Example 3, as observed from the side face.

### EMBODIMENTS FOR CARRYING OUT THE INVENTION

The invention provides a seed crystal holding shaft to be used in a single crystal production device employed in a solution process, wherein

at least a portion of the side face of the seed crystal holding shaft is covered with a reflector member having higher reflectance than the reflectance of the seed crystal holding shaft, and

the reflector member is disposed so as to leave a gap between the reflector member and the seed crystal held on the end face of the seed crystal holding shaft.

In a solution process, C dissolved in the Si—C solution is dispersed by diffusion and convection. In the region near the bottom face of the seed crystal substrate, a temperature gradient can be formed, in which the temperature is lower compared to the inside of the Si—C solution, by utilizing heat extraction through the seed crystal holding shaft, power control of the heating apparatus, and heat radiation from the surface of the Si—C solution. When C dissolved in the inside of the solution where the temperature and the solubility are high, reaches the region near the seed crystal substrate which is at low temperature and has low solubility, a supersaturation state appears and a SiC single crystal is grown on the seed crystal substrate by virtue of supersaturation as a driving force.

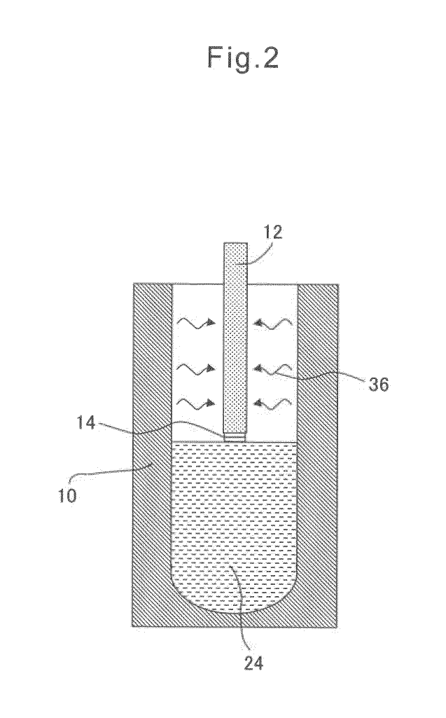

Thus, in order to increase the growth rate of the SiC single crystal, it is effective to increase the degree of supersaturation directly under the crystal growth interface in the Si—C solution. However, it has been found that since the seed crystal holding shaft 12 is also heated by radiant heat 36 from the crucible 10, as shown in FIG. 2, heat extraction through the seed crystal holding shaft 12 is reduced and it is difficult to increase the temperature difference between the inside of the Si—C solution 24 and the region near the crystal growth interface, and this can affect the degree of supersaturation. In conventional methods, therefore, heat extraction through the seed crystal holding shaft tends to be low and it is difficult to achieve a low temperature directly under the crystal growth interface. Furthermore, since it is difficult to increase the temperature difference between the inside of the Si—C solution and the region directly under the crystal growth interface to the desired degree, it is difficult to perform stable increase in the degree of supersaturation, and to increase the growth rate of the SiC single crystal.

As a result of much diligent research with the aim of increasing SiC single crystal growth rates based on this knowledge, the present inventors discovered a seed crystal holding shaft having a member with high reflectance disposed on the side face of the seed crystal holding shaft, in order to increase heat extraction through the seed crystal holding shaft.

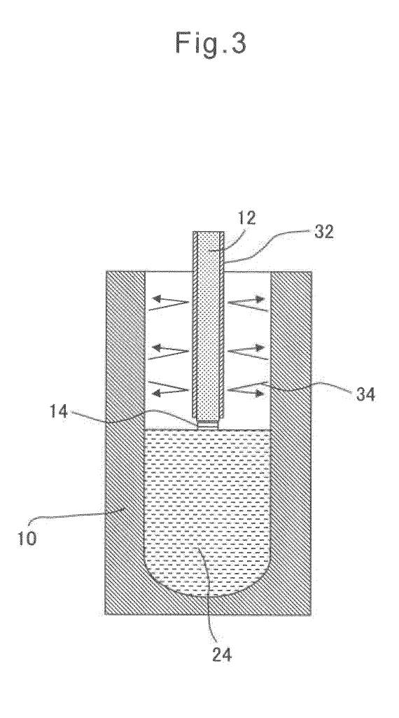

By disposing a reflector member 32 with high reflectance on the side face of the seed crystal holding shaft 12, as shown in FIG. 3, heat input by radiation toward the seed crystal holding shaft 12 is reduced, and temperature increase of the seed crystal holding shaft 12 can be inhibited. This can increase heat extraction through the seed crystal holding shaft 12, lowering the temperature directly under the growth interface in the Si—C solution 24 to increase the degree of supersaturation, and can thus increase the SiC single crystal growth rate.

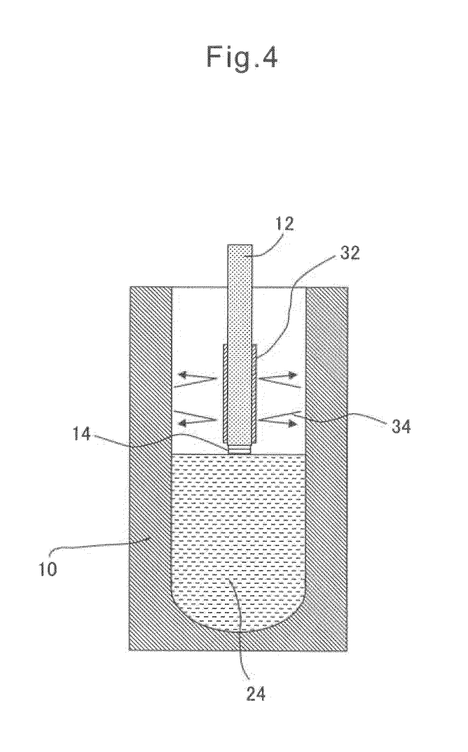

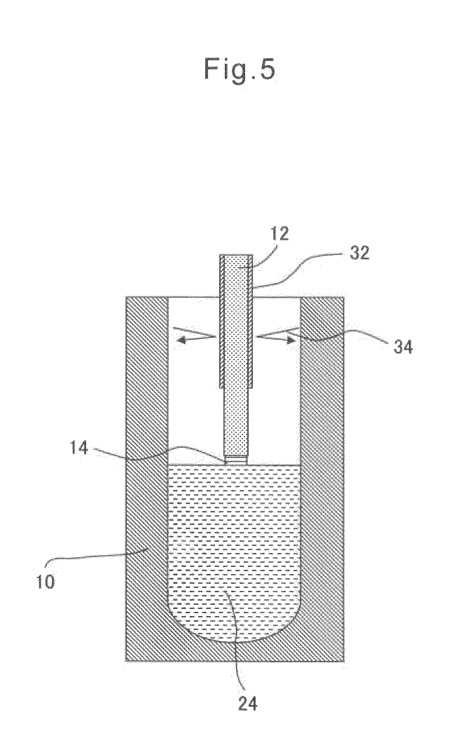

The reflector member 32 may cover at least a portion of the side face of the seed crystal holding shaft inserted into the crucible, and for example, it may cover almost the entirety of the side face of the seed crystal holding shaft 12, as shown in FIG. 3, or it may cover only the lower end or upper end of the side face, or several locations, of the seed crystal holding shaft 12, as shown in FIGS. 4 to 6.

The reflector member 32 covers preferably 50% or greater, more preferably 60% or greater and even more preferably 70% or greater, yet more preferably 80% or greater, even yet more preferably 90% or greater, even yet more preferably 95% or greater and most preferably 100%, of the area of the side face of the portion of the seed crystal holding shaft 12 that is inserted into the crucible 10.

The reflector member 32 is disposed leaving a gap with the seed crystal 14, so that it does not directly contact with the seed crystal 14. If the reflector member 32 and the seed crystal 14 are disposed in contact, it will be difficult to perform uniform heat extraction from the seed crystal 14, the heat extraction distribution within the crystal growth plane will tend to be non-uniform, and macrodefects, such as polycrystals, may be generated in the grown crystal. However, disposing the reflector member 32 with a gap left between it and the seed crystal 14 will facilitate uniform heat extraction from the seed crystal 14, and therefore the heat extraction distribution within the crystal growth plane will tend to be uniform and generation of macrodefects, such as polycrystals, in the grown crystal can be inhibited.

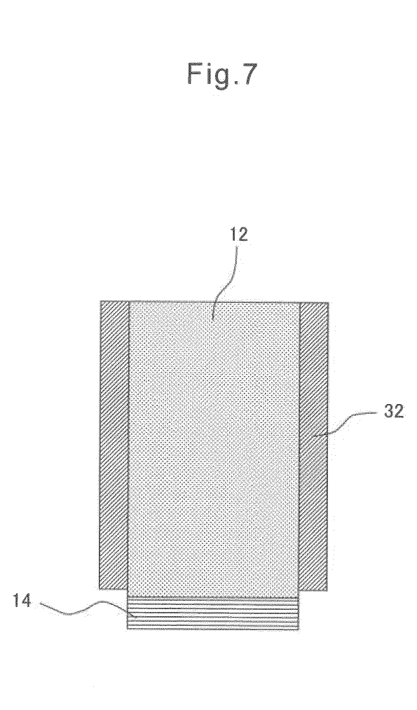

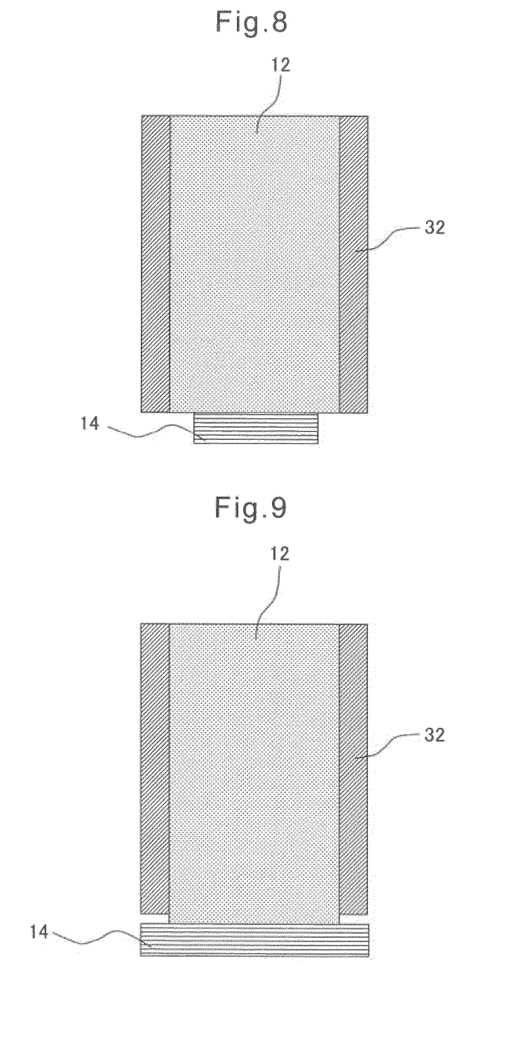

For example, when the end face of the seed crystal holding shaft 12 and the top face of the seed crystal 14 have the same form, as shown in FIG. 7, the reflector member 32 can cover the portion almost up to the bottom edge of the seed crystal holding shaft 12, with the reflector member 32 and the seed crystal 14 still not in contact. If the end face of the seed crystal holding shaft 12 is larger than the top face of the seed crystal 14 and the seed crystal 14 does not protrude from the end face of the seed crystal holding shaft 12, as shown in FIG. 8, the reflector member 32 can cover the entirety up to the bottom edge of the seed crystal holding shaft 12. If the top face of the seed crystal 14 is larger than the end face of the seed crystal holding shaft 12, as shown in FIG. 9, the reflector member 32 is disposed leaving a gap between it and the seed crystal 14, without covering up to the bottom edge of the seed crystal holding shaft 12, so that the reflector member 32 does not contact with the seed crystal 14. In all of these embodiments, the reflector member 32 and the seed crystal 14 are not in contact, and the seed crystal holding shaft 12 is exposed between the reflector member 32 and the seed crystal 14.

For production of a single crystal using such a seed crystal holding shaft, it is preferred to use a seed crystal 14 having a top face that is equal to or smaller than the end face of the seed crystal holding shaft 12. In this case, heat extraction will take place uniformly from the top face of the seed crystal 14 through the seed crystal holding shaft 12, and therefore more uniform heat extraction distribution will be possible within the crystal growth plane.

The reflector member 32 has greater reflectance than the seed crystal holding shaft 12, and has a reflectance of preferably 0.4 or greater, more preferably 0.5 or greater and even more preferably 0.6 or greater.

The term “reflectance” for the purpose of the present specification, refers to the reflectance of heat, i.e. infrared rays (infrared reflectance), and it can be measured, by Fourier transform infrared spectroscopy, for example.

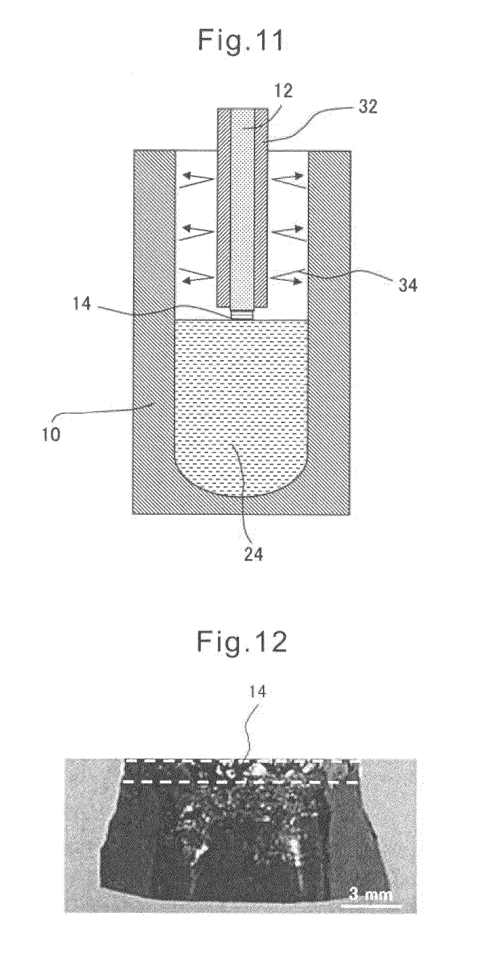

By increasing the thickness of the reflector member 32, it is possible to obtain a greater effect of reducing heat input from the crucible 10 to the seed crystal holding shaft by radiant heat and inhibiting temperature increase of the seed crystal holding shaft 12. For example, rather than the reflector member 32 having a thickness such as shown in FIG. 3, a reflector member 32 having a thickness such as shown in FIG. 11 may cover the seed crystal holding shaft.

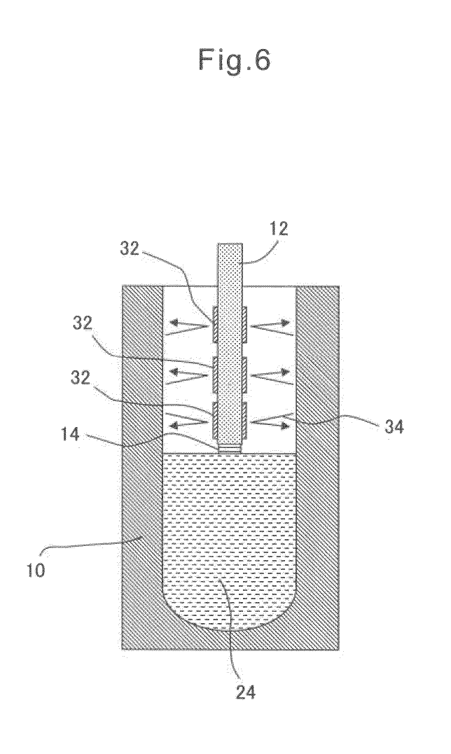

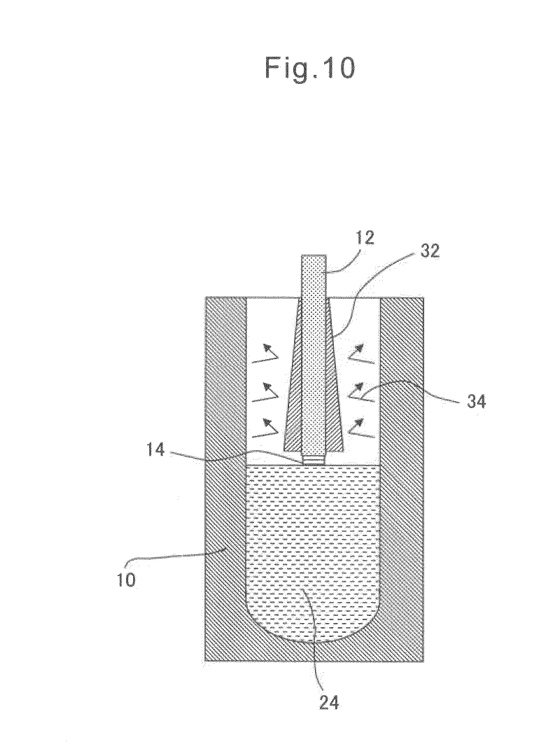

The shape of the reflector member 32 may be any desired shape. For example, as shown in FIG. 3, it may have a uniform thickness along the lengthwise direction of the seed crystal holding shaft 12, or it may have a non-uniform thickness along the lengthwise direction of the seed crystal holding shaft 12. When the reflector member 32 is thick at the lower end and thin at the upper end, as shown in FIG. 10, radiant heat 34 reflected at the reflector member 32 tends to be directed upward in the crucible 10 and away from the surface of the Si—C solution 24, the surface temperature of the Si—C solution 24 tends to be lowered, and a greater degree of supersaturation can be produced. The reflector member 32 may employ a combination of several reflector members, with the different reflector members being disposed on the side face of the seed crystal holding shaft 12 in contact with each other, or the different reflector members 32 may be disposed discretely on the side face of the seed crystal holding shaft 12, as shown in FIG. 6.

Placement of the reflector member 32 on the side face of the seed crystal holding shaft 12 may be performed by using a graphite adhesive. The reflector member 32 may be disposed so as to contact the periphery of the side face of the seed crystal holding shaft 12, or it may be disposed leaving a gap between the reflector member 32 and the seed crystal holding shaft 12 on at least a portion around the periphery of the side face of the seed crystal holding shaft 12.

The reflector member 32 may be a material having higher reflectance than the seed crystal holding shaft that has a reflectance of 0.2, such as a carbon sheet with a reflectance of 0.5, tantalum with a reflectance of 0.4, or tantalum carbide with a reflectance of 0.8, and preferably a carbon sheet is used.

There are no particular restrictions on the carbon sheet, and any commercially available one may be employed. A carbon sheet may be obtained, for example, by subjecting carbon fibers to a roller for dehydration.

The average thickness of the carbon sheet is preferably 0.01 mm or greater, more preferably 0.05 mm or greater, and even more preferably 0.2 mm or greater. A thicker carbon sheet will reduce heat input from the crucible 10 to the seed crystal holding shaft 12 by radiant heat and will thus inhibit temperature increase of the seed crystal holding shaft 12, thereby allowing a greater effect to be obtained for increasing heat extraction from the crystal growth interface.

Covering the side face section of the seed crystal holding shaft 12 by the carbon sheet can be performed by using an adhesive, and preferably a graphite adhesive.

According to the invention, the reflector member is different from a heat-insulating material, and the effect of the invention cannot be obtained by using a heat-insulating material instead of a reflector member. The desired improvement in the SiC single crystal growth rate cannot be obtained even if a heat-insulating material covers the seed crystal holding shaft, one reason being that using a heat-insulating material causes the region near the crystal growth interface to also be thermally insulated, making it impossible to reach a low temperature, and therefore the desired degree of supersaturation cannot be obtained.

The seed crystal holding shaft is a shaft made of graphite that holds the seed crystal substrate on its end face. The seed crystal holding shaft may have any desired shape, such as cylindrical or columnar, and for example, there may be used a graphite shaft with the same end face shape as the top face of the seed crystal. The seed crystal holding shaft may usually have a length of 50 to 1000 mm.

The seed crystal holding shaft is used in a single crystal production device employed in a solution process, and may be used, for example, in a single crystal production device for SiC, GaN or BaTiO₃, and especially in a SiC single crystal production device.

A Si—C solution is used for production of a SiC single crystal. A Si—C solution is a solution in which C is dissolved, where the solvent is a molten liquid of Si or Si/X (X being one or more metals other than Si). X is not particularly restricted so long as it is one or more metals and can form a liquid phase (solution) that is in a state of thermodynamic equilibrium with SiC (solid phase). Suitable examples of X metals include Ti, Mn, Cr, Ni, Ce, Co, V and Fe. For example, Cr, Ni and the like may be loaded into the crucible in addition to Si, to form a Si—Cr solution, Si—Cr—Ni solution or the like.

The Si—C solution preferably has a surface temperature of 1800° C. to 2200° C., which will minimize fluctuation in the amount of dissolution of C into the Si—C solution.

Temperature measurement of the Si—C solution can be carried out by using a thermocouple or radiation thermometer. From the viewpoint of high temperature measurement and preventing inclusion of impurities, the thermocouple is preferably a thermocouple comprising tungsten-rhenium wire covered with zirconia or magnesia glass, placed inside a graphite protection tube.

The invention further provides a method for producing a SiC single crystal by a solution process in which a SiC seed crystal held on a seed crystal holding shaft is contacted with a Si—C solution that has been heated so as to have a temperature gradient with increasing temperature from the inside to the surface of the Si—C solution in a crucible by a heating apparatus situated around the crucible, to grow a SiC single crystal from the seed crystal, wherein at least a portion of the side face of the seed crystal holding shaft is covered with a reflector member having higher reflectance than the reflectance of the seed crystal holding shaft, and the reflector member is disposed so as to leave a gap between the reflector member and the seed crystal.

According to this production method, a seed crystal holding shaft has a member with high reflectance on the side face of the seed crystal holding shaft, as explained above with regard to the seed crystal holding shaft, and when a SiC single crystal is produced by a solution process, heat input into the seed crystal holding shaft by radiation can be reduced to inhibit temperature increase of the seed crystal holding shaft, and thereby increasing heat extraction through the seed crystal holding shaft to lower the temperature of the Si—C solution directly under the growth interface of the single crystal so that the degree of supersaturation can be increased to increase the SiC single crystal growth rate.

The location and method of placement of the reflector member on the seed crystal holding shaft, and the reflectance, material, thickness, and shape of the reflector member, as well as the material and shape of the seed crystal holding shaft, in this production method are the same as explained above in regard to the seed crystal holding shaft.

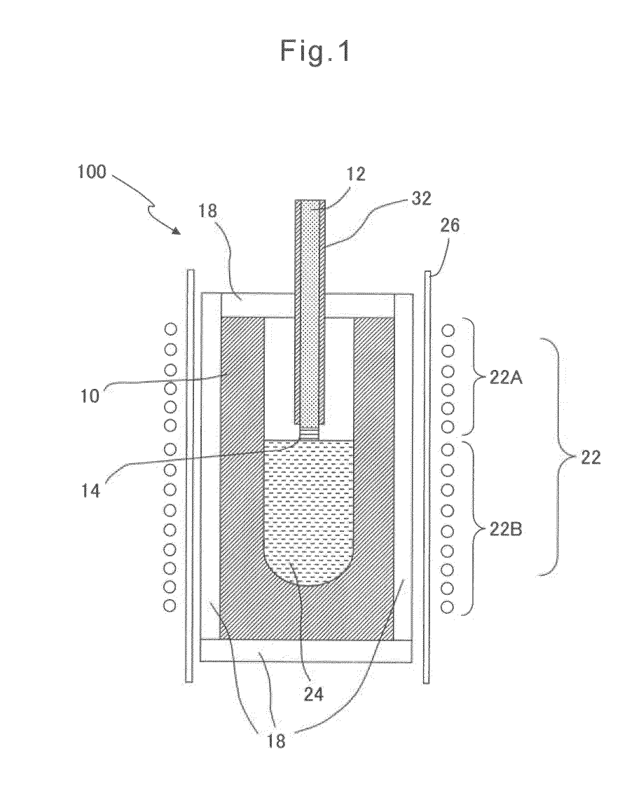

FIG. 1 shows an example of a SiC single crystal production device suitable for carrying out the invention. The illustrated SiC single crystal production device 100 includes a crucible 10 and a vertically movable graphite shaft 12, wherein the crucible 10 contains a Si—C solution 24 in which C is dissolved in a molten liquid of Si or Si/X, the Si—C solution 24 forms a temperature gradient decreasing from the inside of the Si—C solution toward the surface of the solution, and the vertically movable graphite shaft 12 holds, at an end, a seed crystal substrate 14, which is contacted with the Si—C solution 24 to allow growth of the SiC single crystal from the seed crystal substrate 14. The crucible 10 and the seed crystal holding shaft 12 are preferably rotated.

The Si—C solution 24 is prepared by loading the starting materials into the crucible and heating them to a melt to dissolve C into the prepared Si or Si/X molten liquid. If the crucible 10 is a carbonaceous crucible, such as a graphite crucible, or SiC crucible, C will dissolve into the molten liquid by dissolution of the crucible 10, thereby forming a Si—C solution. This will avoid the presence of undissolved C in the Si—C solution 24, and prevent waste of SiC by deposition of the SiC single crystal onto the undissolved C. The supply of C may be performed by utilizing a method of, for example, blowing in hydrocarbon gas or loading a solid C source together with the molten liquid starting material, or these methods may be combined together with dissolution of the crucible.

The outer periphery of the crucible 10 is covered with a heat-insulating material 18 for thermal insulation. These are housed together inside a quartz tube 26. A high-frequency coil 22 for heating is disposed around the outer periphery of the quartz tube 26. The high-frequency coil 22 may be constructed from an upper level coil 22A and a lower level coil 22B, the upper level coil 22A and lower level coil 22B each being independently controllable.

Since the temperatures of the crucible 10, heat-insulating material 18, quartz tube 26, and high-frequency coil 22 become high, they are situated inside a water-cooling chamber. The water-cooling chamber is provided with a gas inlet and a gas exhaust vent to allow atmospheric modification in the device.

The temperature of the Si—C solution will usually have a temperature distribution with a lower temperature at the surface than the inside of the Si—C solution due to radiation and the like. Further, by adjusting the number of turns and spacing of the high-frequency coil 22, the positional relationship of the high-frequency coil 22 and the crucible 10 in the height direction, and the output of the high-frequency coil, it is possible to form a temperature gradient in the Si—C solution in the direction perpendicular to the surface of the Si—C solution 24 so that the upper portion of the solution contacting the seed crystal substrate 14 is at low temperature and the lower portion (inside) of the solution is at high temperature. For example, the output of the upper level coil 22A may be smaller than the output of the lower level coil 22B, to form a temperature gradient in the Si—C solution 24 in which the upper portion of the solution is at low temperature and the lower portion of the solution is at high temperature. The temperature gradient is preferably 1-100° C./cm and more preferably 10-50° C./cm, in a range of a depth of up to 30 mm from the solution surface.

In some embodiments, meltback may be carried out in which the surface layer of the seed crystal substrate is dissolved in the Si—C solution and removed before SiC single crystal growth. Since the surface layer of the seed crystal substrate on which the SiC single crystal is grown may have an affected layer, such as a dislocation, a natural oxide film, or the like, dissolving and removing these before growing the SiC single crystal is effective for growing a high-quality SiC single crystal. Although the dissolving thickness will differ depending on the processed state of the seed crystal substrate surface, it is preferably about 5 to 50 μm for sufficient removal of the affected layer or natural oxide film.

The meltback may be performed by forming in the Si—C solution a temperature gradient in which the temperature increases from the inside of the Si—C solution toward the surface of the solution, i.e. a temperature gradient in the reverse direction from growth of the SiC single crystal. It is possible to form a temperature gradient in this reverse direction by controlling output from the high-frequency coil.

The meltback can also be performed without forming a temperature gradient in the Si—C solution, by simply dipping the seed crystal substrate in the Si—C solution that has been heated to a higher temperature than the liquidus temperature. In this case, the dissolution rate increases with higher Si—C solution temperature, but control of the amount of dissolution is difficult, while a low temperature can slow the dissolution rate.

In some embodiments, the seed crystal substrate may be preheated in advance, and then the same is contacted with the Si—C solution. If the seed crystal substrate at a low temperature is contacted with the Si—C solution at high temperature, heat shock dislocation may be generated in the seed crystal. Preheating the seed crystal substrate before contacting the seed crystal substrate with the Si—C solution prevents heat shock dislocation and is effective for growth of a high-quality SiC single crystal. The seed crystal substrate may be heated together with the seed crystal holding shaft. In this case, heating of the seed crystal holding shaft is stopped after contact of the seed crystal substrate with the Si—C solution and before growth of the SiC single crystal. Alternatively, the Si—C solution may be heated to the temperature for crystal growth after contacting the seed crystal with the Si—C solution at a relatively low temperature. This also prevents heat shock dislocation and is effective for growing a high-quality SiC single crystal.

### EXAMPLES

### Common Conditions

The following conditions were common to Example 1 and Comparative Examples 1 to 3. For each example, a single crystal production device 100, as shown in FIG. 1, was used. However, the presence, position and shape of the reflector member 32 were different for each example. In a graphite crucible 10 with an inner diameter of 40 mm and a height of 125 mm containing a Si—C solution 24 there were charged Si/Cr/Ni in an atomic compositional ratio of 54:40:6, as a molten liquid starting material. The air in the single crystal production device was exchanged with argon. A high-frequency coil 22 situated around the periphery of the graphite crucible 10 was electrified to melt the starting material in the graphite crucible 10 by heating, thereby forming a Si/Cr/Ni alloy molten liquid. A sufficient amount of C was dissolved into the Si/Cr/Ni alloy molten liquid from the graphite crucible 10 to form a Si—C solution 24.

The outputs of the upper level coil 22A and lower level coil 22B were adjusted to heat the graphite crucible 10, forming a temperature gradient in which the temperature decreased from the inside of the Si—C solution 24 toward the surface of the solution. Formation of the prescribed temperature gradient was confirmed by using a vertically movable thermocouple comprising a zirconia-coated tungsten-rhenium wire placed in a graphite protection tube, to measure the temperature of the Si—C solution 24. Output of the high-frequency coils 22A and 22B was controlled to adjust the temperature to 2000° C. on the surface of the Si—C solution 24. With the surface of the Si—C solution as the low-temperature side, the temperature difference between the temperature at the surface of the Si—C solution into which the seed crystal substrate was to be dipped and the temperature at a depth of 10 mm in the vertical direction from the surface of the Si—C solution 24 toward the inside of the solution was 25K.

### Example 1

A cylindrical graphite seed crystal holding shaft 12 with a reflectance of 0.2, a diameter of 12 mm, and a length of 200 mm was prepared, and a carbon sheet (Tomoe Engineering Co., Ltd.) with a reflectance of 0.5 and a thickness of 0.2 mm was used as a reflector member 32 and disposed at a location 5 mm from the bottom edge to the top edge of the side face of the seed crystal holding shaft 12, by using a graphite adhesive.

A discoid 4H—SiC single crystal with a thickness of 1 mm and a diameter of 12 mm was prepared and used as the seed crystal substrate 14. The top face of the seed crystal substrate 14 was bonded to about the center section of the end face of the seed crystal holding shaft 12 by using a graphite adhesive, with the bottom face of the seed crystal substrate 14 as the Si surface. It was bonded in such a manner that the top face of the seed crystal substrate 14 did not protrude from the end face of the seed crystal holding shaft 12. During this time, the seed crystal substrate 14 and the carbon sheet did not contact, and a gap of 5 mm was present between the top face of the seed crystal substrate 14 and the bottom edge of the carbon sheet.

Next, the seed crystal holding shaft 12 holding the seed crystal substrate 14 was lowered, and the seed crystal substrate 14 was contacted with the Si—C solution 24 so that the bottom face of the seed crystal substrate 14 matched the surface location of the Si—C solution 24, and crystal growth was carried out for 10 hours. During this time, the graphite crucible 10 was rotated at 5 rpm and the seed crystal holding shaft 12 was rotated at 40 rpm, both in the same direction. The growth rate of the SiC single crystal was 0.64 mm/h, and the growth amount was 6.4 mm. FIG. 12 shows a photograph of the outer appearance of the obtained SiC single crystal as viewed from the side face. The top portion surrounded by a dashed line is the seed crystal substrate 14. No polycrystals or other macrodefects were seen in the obtained grown crystal.

### Comparative Example 1

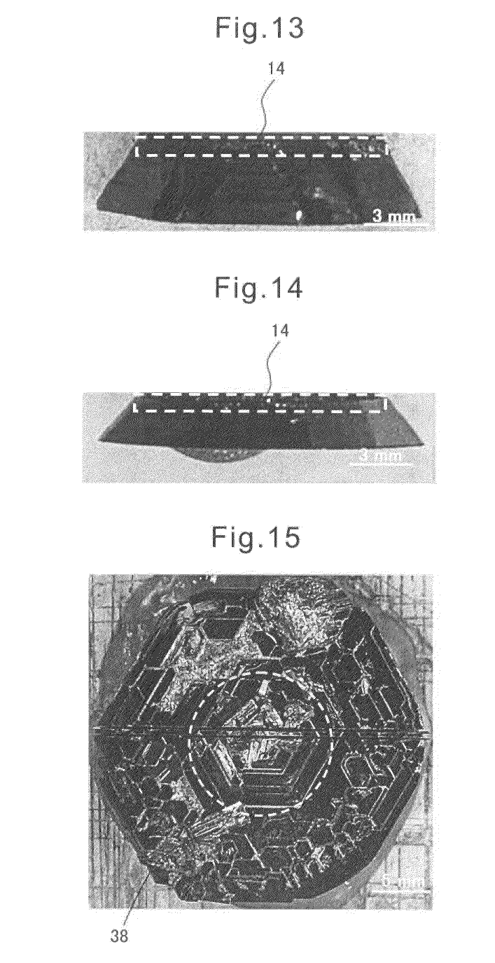

A SiC single crystal was grown in the same manner as in Example 1, except that no reflector member was used. The growth rate of the SiC single crystal was 0.32 mm/h, and the growth amount was 3.2 mm. FIG. 13 shows a photograph of the outer appearance of the obtained SiC single crystal as viewed from the side face. The top portion surrounded by a dashed line is the seed crystal substrate 14. No polycrystals or other macrodefects were seen in the obtained grown crystal.

### Comparative Example 2

Instead of a reflector member, a carbon molded heat-insulating material with a thickness of 2 mm was disposed from a location 5 mm from the bottom edge up to the top edge of the side face of the seed crystal holding shaft 12, by using a graphite adhesive.

Using the same seed crystal substrate 14 as in Example 1, the top face of the seed crystal substrate 14 was bonded to about the center section of the end face of the seed crystal holding shaft 12 by using a graphite adhesive, with the bottom face of the seed crystal substrate 14 as the Si surface. Bonding was in such a manner that the top face of the seed crystal substrate 14 did not protrude from the end face of the seed crystal holding shaft 12. During this time, the seed crystal substrate 14 did not contact with the heat-insulating material, and a gap of 5 mm was present between the top face of the seed crystal substrate 14 and the bottom edge of the heat-insulating material.

Next, the seed crystal holding shaft 12 holding the seed crystal substrate 14 was lowered, the seed crystal substrate 14 was contacted with the Si—C solution 24 so that the bottom face of the seed crystal substrate 14 matched the surface location of the Si—C solution 24, and crystal growth was carried out for 10 hours. During this time, the graphite crucible 10 was rotated at 5 rpm and the seed crystal holding shaft 12 was rotated at 40 rpm, both in the same direction. The growth rate of the SiC single crystal was 0.13 mm/h, and the growth amount was 1.3 mm. FIG. 14 shows a photograph of the outer appearance of the obtained SiC single crystal as viewed from the side face. The top portion surrounded by a dashed line is the seed crystal substrate 14. No polycrystals or other macrodefects were seen in the obtained grown crystal.

### Comparative Example 3

A cylindrical graphite seed crystal holding shaft 12 with a reflectance of 0.2, a diameter of 12 mm and a length of 200 mm was prepared, and a carbon sheet (Tomoe Engineering Co., Ltd.) with a reflectance of 0.5 and a thickness of 0.2 mm was used as a reflector member 32 and disposed over the entire side face of the seed crystal holding shaft 12, by using a graphite adhesive.

A discoid 4H—SiC single crystal with a thickness of 1 mm and a diameter of 25 mm was prepared and used as the seed crystal substrate 14. The top face of the seed crystal substrate 14 was bonded to about the center section of the end face of the seed crystal holding shaft 12 by using a graphite adhesive, with the bottom face of the seed crystal substrate 14 as the Si surface. During this time, a portion of the top face of the seed crystal substrate 14, which was larger than the end face of the seed crystal holding shaft 12, contacted with the carbon sheet.

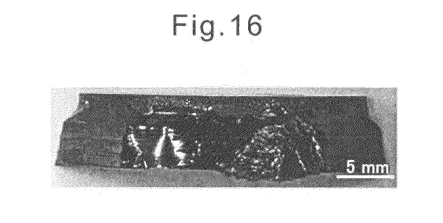

Next, the seed crystal holding shaft 12 holding the seed crystal substrate 14 was lowered, the seed crystal substrate 14 was contacted with the Si—C solution 24 so that the bottom face of the seed crystal substrate 14 matched the surface location of the Si—C solution 24, and crystal growth was carried out for 10 hours. During this time, the graphite crucible 10 was rotated at 5 rpm and the seed crystal holding shaft 12 was rotated at 40 rpm, both in the same direction. The growth rate of the SiC single crystal was 0.60 mm/h. FIG. 15 shows a photograph of the outer appearance of the obtained SiC single crystal as viewed from the bottom face, and FIG. 16 shows a photograph of the outer appearance as viewed from the side face. The dotted line section in FIG. 15 represents the region 38 directly under the seed crystal. The obtained crystal had macrodefects, such as polycrystals, generated at locations corresponding to the border between the seed crystal holding shaft 12 and the carbon sheet.

### EXPLANATION OF SYMBOLS

100 Single crystal production device
10 Crucible
12 Seed crystal holding shaft
14 Seed crystal substrate
18 Heat-insulating material
22 High-frequency coil
22A Upper level high-frequency coil
22B Lower level high-frequency coil
24 Si—C solution
26 Quartz tube
32 Reflector member
34 Radiant heat with reflector member
36 Radiant heat without reflector member
38 Region directly under seed crystal

1. A seed crystal holding shaft to be used in a single crystal production device employed in a solution process, wherein
at least a portion of the side face of the seed crystal holding shaft is covered with a reflector member having higher reflectance than the reflectance of the seed crystal holding shaft, and
the reflector member is disposed so as to leave a gap between the reflector member and the seed crystal held on the end face of the seed crystal holding shaft.

2. The seed crystal holding shaft according to claim 1, wherein at least 50% of the side face of the seed crystal holding shaft is covered by the reflector member.

3. The seed crystal holding shaft according to claim 1, wherein the reflectance of the reflector member is 0.4 or greater.

4. The seed crystal holding shaft according to claim 1, wherein the reflector member is a carbon sheet.

5. The seed crystal holding shaft according to claim 4, wherein the average thickness of the carbon sheet is 0.05 mm or greater.

6. The seed crystal holding shaft according to claim 1, wherein the seed crystal holding shaft is made of graphite.

7. A method for producing a SiC single crystal by a solution process in which a SiC seed crystal held on a seed crystal holding shaft is contacted with a Si—C solution that has been heated so as to have a temperature gradient with increasing temperature from the inside to the surface of the Si—C solution in a crucible by a heating apparatus situated around the crucible, to grow a SiC single crystal from the seed crystal, wherein
at least a portion of the side face of the seed crystal holding shaft is covered with a reflector member having higher reflectance than the reflectance of the seed crystal holding shaft, and
the reflector member is disposed so as to leave a gap between the reflector member and the seed crystal.

8. The method according to claim 7, wherein at least 50% of the side face of the seed crystal holding shaft is covered by the reflector member.

9. The method according to claim 7, wherein the reflectance of the reflector member is 0.4 or greater.

10. The method according to claim 7, wherein the reflector member is a carbon sheet.

11. The method according to claim 10, wherein the average thickness of the carbon sheet is 0.05 mm or greater.

12. The method according to claim 7, wherein the seed crystal holding shaft is made of graphite.
